(19) United States
(12) Patent Application Publication
(10) Pub. No.: US 2023/0122836 A1
(43) Pub. Date: Apr. 20, 2023

(54) TEMPERATURE REGULATING DEVICE ASSEMBLY FOR A SEMICONDUCTOR LASER

(71) Applicants: Sergey GULAK, Kharkiv (UA); Volodymyr VAKH, Lviv region (UA)

(72) Inventors: Sergey GULAK, Kharkiv (UA); Volodymyr VAKH, Lviv region (UA)

(21) Appl. No.: 17/909,663

(22) PCT Filed: Apr. 16, 2020
(86) PCT No.: PCT/IB2020/053597

§ 371 Date: Sep. 6, 2022

(51) Int. Cl. H01S 5/024; H01S 5/02315; H01S 5/02251

(52) U.S. Cl. CPC H01S 5/02415; H01S 5/02315; H01S 5/02251

(57) ABSTRACT

The present invention relates to an assembly of a temperature regulating device for a semiconductor laser.

The essence of the present invention is that a flat thermally conductive surface of said device is used as a thermally conductive base surface, the assembly further contains two fixing plates which are rigidly fastened to said thermally conductive base surface and adjoin the opposite lateral sides of a lower thermally insulated surface of a thermoelectric element, said surface being in contact with the thermally conductive base surface to prevent the longitudinal and transverse displacements of the thermoelectric element along the thermally conductive base surface, and a thermally conductive plate is rigidly fastened to the thermally conductive base surface and is thermally insulated therefrom.

### FIEND OF THE INVENTION

The present invention relates to an assembly of a temperature regulating device for a semiconductor laser.

### DESCRIPTION OF THE PRIOR ART

The emergence and reduction in the cost of manufacture of semiconductor lasers make it possible to widen the sphere of their application in various industries. Semiconductor lasers are widely used in teleorientation, navigation, and optical communication systems, for example, in guidance systems of guided weapons (for example, as a part of an anti-tank missile system); please refer to the prior art Nos. RU2126522, RU2261463, and RU2382315.

The operation of semiconductor lasers is accompanied by a considerable heat release. At the same time, the efficient operation of semiconductor lasers is only achieved if they operate within a permissible temperature range. In order to maintain a predetermined temperature range of semiconductor laser operation, various assemblies of a temperature regulating device for a semiconductor laser are employed, please refer to the prior art Nos. GB2458338, US2017302055A1, U.S. Pat. Nos. 9,490,412, 9,001,856, 6,697,399, 6,219,364, 5,195,102 which disclose Seebeck and Peltier effect thermoelectric elements, please refer to the prior art Nos. RU2475889, U.S. Pat. Nos. 5,009,717, 241,859.

Generally, a thermoelectric element comprises two thermally insulated surfaces between which a semiconducting layer consisting of a set of n-type and p-type semiconductors (thermocouples) is disposed. Upon application of electric current to the semi-conductive layer, one thermally insulated surface is cooled down while the opposite thermally insulated surface is heated.

For low-power semiconductor lasers, an embodiment is possible in which the thermoelectric element is disposed in the semiconductor laser case itself. But such semiconductor lasers are expensive to manufacture and have a low power, a low reliability, and low temperature regulation efficiency associated with a limited volume of the semiconductor laser case. Therefore, what is needed for the semiconductor lasers are the development and use of various assemblies of a temperature regulating device for a semiconductor laser. Assemblies of a temperature regulating device for a semiconductor laser (hereinafter called the “temperature regulating assembly” or “assembly”), in which a thermoelectric element is used, are disclosed, for example, in Nos. U.S. Pat. No. 6,697,399, CH698316.

So, a prior art assembly of a temperature regulating device for a semiconductor laser disclosed in U.S. pat. No. 6,697,399 comprises a thermally conductive base surface, which a thermally insulated surface of a thermoelectric element adjoin. Said thermoelectric element consists of two thermally insulated surfaces between which a semi-conductive layer consisting of a set of n-type and p-type semiconductors (thermocouples) is disposed. A thermally conductive plate adjoins the opposite thermally insulated surface of the thermoelectric element. A semiconductor laser is fastened rigidly to the opposite side of said opposite thermally insulated surface, and said assembly comprises at least one temperature sensor of the semiconductor laser.

A design feature of the above-mentioned prior art assembly is that the thermally conductive base surface is a flat thermally conductive plate to which the thermoelectric element is fastened. The thermally conductive plate and the semiconductor laser are covered with a case, which is fastened to the thermally conductive plate and covers the semiconductor laser. The temperature regulating assembly so produced is then fastened within a device case by means of the thermally conductive plate. When using this prior art assembly, all the heat is transferred to the thermally conductive plate.

The operation of the thermoelectric element to ensure temperature regulation for the semiconductor laser is based on the temperature readings, which come to the control system from the temperature sensor, as disclosed in CH698316, where, based on temperature data obtained, the value of electric current that is fed to the thermoelectric element to maintain the predetermined temperature of semiconductor laser operation is determined.

The authors of the proposed invention have found that the operation of semiconductor lasers in teleorientation, navigation, and other systems arranged on various vehicles (for example, as a part of an anti-tank missile system), guided missiles, or in rocket and space equipment, occurs under exposure to external mechanical impacts such as vibration, shocks, and linear loads, among others. This results in large differently directed mechanical actions, which may lead to both longitudinal and transverse displacements of parts of the temperature regulating assembly and loosening its fasteners this, as a general result, causing a premature failure of the temperature regulating assembly.

Furthermore, the disadvantages of the prior art technical solution include large overall dimensions due to the use of the base thermally conductive plate, at which the case is installed, which dimensions used to cause difficulties in using semiconductor lasers in already existing devices (teleorientation, navigation, and guidance systems), in which semiconductor lasers are planned to be employed.

Moreover, the disadvantages of the prior art technical solution include the complexity of checking the performance and of the replacement of parts (the semiconductor laser, the thermoelectric element, and the temperature sensor).

In addition, the disadvantages of the prior art technical solution include large expenses and materials consumption associated with the manufacture of the thermally conductive base surface, for which the thermally conductive plate is used. It should be noted that the use of semiconductor lasers in already existing systems relates to a low-rate production and is associated with their utilization in various, already existing modifications of devices, systems, for which semiconductor lasers of various power may be used, therefore, a need arises to design permanently the thermally conductive base plate customized for a particular device this meaning additional expenses.

Furthermore, the disadvantages of the prior art technical solution include a small surface of the thermally conductive base plate, through which the semiconductor laser is temperature regulated.

Also, the disadvantages of the prior art technical solution include poor convective heat exchange due to the arrangement of the semiconductor laser within the case.

### SUMMARY OF THE INVENTION

In view of the above-mentioned disadvantages of the prior art, it is the object of the present invention to improve the efficiency of temperature regulation of a semiconductor laser under exposure to external mechanical impacts such as vibration, shocks, and linear loads, among others.

It is another object of the present invention to improve the reliability of operation of the temperature regulating assembly for the semiconductor laser under exposure to external mechanical impacts.

It is another object of the present invention to improve the reliability of fastening the semiconductor laser.

It is a further object of the present invention to simplify the design and to reduce material consumption.

It is another object of the present invention to simplify installation.

It is yet another object of the present invention to simplify the test of the working ability of the parts of the temperature regulating assembly for the semiconductor laser.

It is a further object of the present invention to simplify the replacement of the parts of the temperature regulating assembly for the semiconductor laser.

It is another object of the present invention to eliminate the above-mentioned disadvantages of the prior art.

It is yet another object of the present invention to widen the arsenal of design implementation of the temperature regulating assembly for the semiconductor laser.

The above-mentioned and other features and advantages of this invention, and manner of the attaining them, will become more apparent and invention will be better understood by reference to the following description of embodiments of the invention taken in conjunction with the accompanying drawings.

In the prior art assembly of a temperature regulating device for a semiconductor laser, which comprises a thermally conductive base surface, which a thermally insulated surface of a thermoelectric element adjoins, the thermoelectric element consisting of two thermally insulated surfaces, between which a semiconducting layer consisting of a set of n-type and p-type semiconductors is disposed, a thermally conductive plate, at the opposite side whereof the semiconducting layer is rigidly fastened, adjoining the opposite thermally insulated surface of the thermoelectric element, said assembly comprising further at least one operating temperature sensor of the semiconductor laser, in at least one embodiment of the present invention, as the thermally conducting base surface, a flat thermally conducting surface of said device is used, the assembly further comprising two fixing plates, which are rigidly fastened to said thermally conducting base surface and adjoin opposite lateral sides of the lower thermally conducting surface of the thermoelectric element, which surface contacts to the thermally conducting surface base to prevent both longitudinal and transverse displacements of the thermoelectric element along the thermally conductive base surface, and the thermally conductive plate is rigidly fastened to the thermally conductive base surface and is thermally insulated therefrom.

According to one aspect of the present invention, at least one of the fixing plates comprises two side projections, which adjoin the lateral sides of the lower thermally insulated surface of the thermoelectric element.

According to another aspect of the present invention, the assembly further comprises a bearing pad rigidly fastened to the thermally conductive base surface; two projections are disposed at the upper surface of the bearing pad, between which projections a fiber optical output of the semiconductor laser is arranged, said output resting against the upper surface of the bearing pad.

According to yet another aspect of the present invention, the assembly comprises a limiting clamp, which is secured at two projections arranged at the upper surface of the bearing pad.

According to a further aspect of the present invention, the thermoelectric element, the thermally conductive plate, and the semiconductor laser are secured with the help of fasteners.

According to another aspect of the present invention, bolts, nuts, screws, screw nails, self-driving screws, plugs, rivets, washers, pins, studs or their combinations are used as said fasteners.

According to yet another aspect of the present invention, a thermal paste-based thermally conductive layer is formed between the contact surfaces, namely the lower thermally insulated surface of the thermoelectric element and the thermally conductive base surface.

According to another aspect of the present invention, a thermal paste-based thermally conductive layer is formed the contact surfaces, namely the upper thermally insulated surface of the thermoelectric element and the thermally conductive base surface.

According to yet another aspect of the present invention, a thermal paste-based thermally conductive layer is formed at the contact surface of the thermally conductive plate and the semiconductor laser.

The present invention makes it possible to increase materially the thermally conductive base surface while ensuring the reliable fastening thereto of the thermoelectric element, which is secured against both longitudinal and transverse displacements the thermally conductive plate being also rigidly fastened to the thermally conductive base surface and pressing the thermoelectric element to the thermally conductive base surface. Furthermore, the fasteners that fasten the thermally conducting to the thermally conductive base surface prevent both longitudinal and transverse displacements of the thermoelectric element along the thermally conductive base surface. The thermally conductive plate is thermally insulated from the thermally conductive base surface and, as a result whereof, heat transfer between the thermally conductive base surface and the thermally conductive plate is prevented, this also improving the operating efficiency of the assembly in accordance with the present invention.

The presence of the fixing plates simplifies the fastening of the thermoelectric element and prevents both longitudinal and transverse displacements thereof along the thermally conductive base surface.

Moreover, the present invention makes it possible to increase convective heat exchange (temperature regulation) of the semiconductor laser during its operation for the thermally conductive plate and the external surface of the semiconductor laser will interact with ambient air present in the volume of the device case where the temperature regulating assembly is installed.

Adjoining the end sides of the lower thermally insulated surfaces of the thermoelectric element, which contacts to the thermally conductive base surface, makes it possible to insulate thermally the opposite (lower and upper) thermally insulated surfaces of the thermoelectric element from each other, improving thereby the operating efficiency thereof.

The presence of the side projections of the fixing plate, which projections adjoin the lateral sides of the lower thermally insulated surface, which contacts the thermally conductive base surface, makes it possible to improve the reliability of fastening the thermoelectric element to the thermally conductive base surface and to prevent the longitudinal or transverse displacement of the thermoelectric element.

The presence of the bearing pad fastened to the thermally conductive base surface makes it possible to fasten rigidly the fiber optical output of the semiconductor laser with respect to the input thereof this improving the performance reliability of the semiconductor laser.

Furthermore, the present invention makes it possible to simplify the installation, disassembly, and replacement of parts of the temperature regulating device assembly for the semiconductor laser. In doing so, spring washers, bolts, nuts, check nuts, screws, screw nails, self-driving screws, plugs, rivets, ratchet washers and tab washers, pins, studs, thread lockers, or their combinations may be used as fasteners. It should be noted separately that the fasteners of the thermally conductive plate to the thermally conductive base surface restrict also the thermoelectric element against the longitudinal or transverse displacement along the thermally conductive base surface this also being an advantage of the present invention.

The presence of the thermal paste-based thermally conductive layers improves the contact of surfaces this improving temperature regulation and the effectiveness of using the present invention.

### BRIEF DESCRIPTION OF THE APPENDED DRAWINGS

In the discussion of the embodiments of the present invention, narrow terminology is used. The present invention is not, however, limited by the accepted terms and it should be kept in mind that each and every such term covers all the equivalent solutions, which operate in a similar manner and are used to solve the same tasks.

The embodiments of the present invention will be now described in more detail with reference to the accompanying drawings, in which:

FIG. 1 is a perspective view with the temperature regulation assembly partly in section in accordance with the present invention;

FIG. 2 is an exploded view of the temperature regulating device assembly for a semiconductor laser in accordance with the present invention; and

FIG. 3 is a side view of the temperature regulating device assembly in accordance with the present invention.

### LIST OF THE REFERENCE NUMERALS

1 semiconductor laser

1₁ fiber optical output of the semiconductor laser 1

1₂ fastener of the semiconductor laser 1

1₃ wires to feed electric current to the semiconductor laser 1

2 base of the temperature regulating assembly

3 thermoelectric element

3₁ lower thermally insulated surface of the thermoelectric element 3, which contacts a thermally conductive base surface 5.

3₂ upper thermally insulated surface of the thermoelectric element 3, which contacts a thermally conductive plate 4

3₃ semiconducting layer of the thermoelectric element 3

3₄ wires to feed electric current to the semiconducting layer 3₃ of the thermoelectric element 3

4 thermally conductive plate

4₁ fastener of the thermally conductive plate 4 at the thermally conductive base surface 2

5 thermally conductive base surface

5₁, 5₂ fixing plates

5₃ fastener of the fixing plates 5₁, 5₂

5₄ side projections of the fixing plate 5₁

6 temperature sensor

6₁ fastener of the temperature sensor 6 at the thermally conductive plate 4

7 bearing pad

7₁ upper surface of the bearing pad 7

7₂ projections of the bearing pad 7

7₃ limiting clamp

### DETAILED DESCRIPTIONS OF PREFERRED EMBODIMENTS OF THE INVENTION

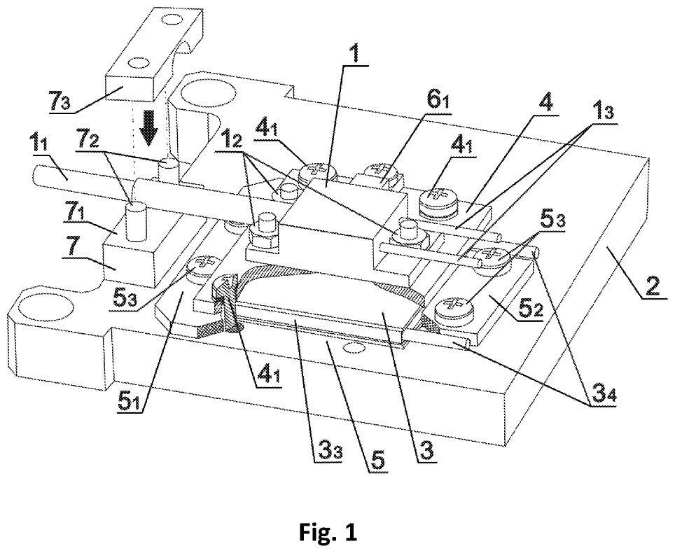

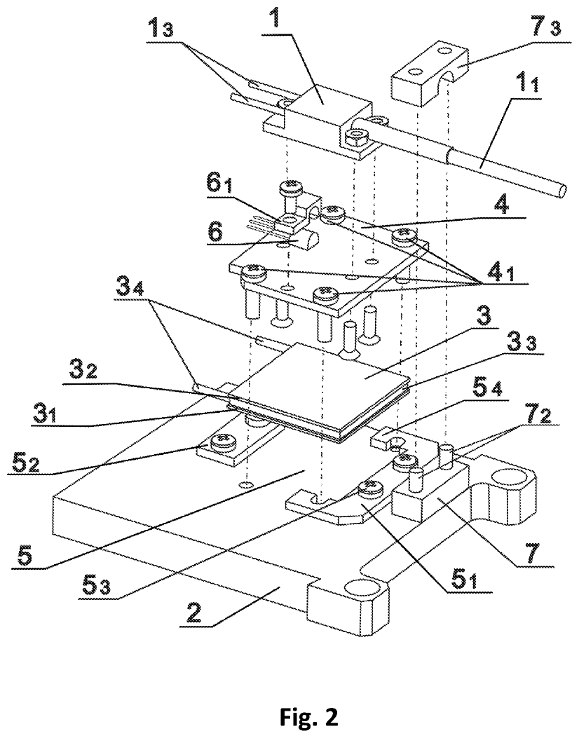

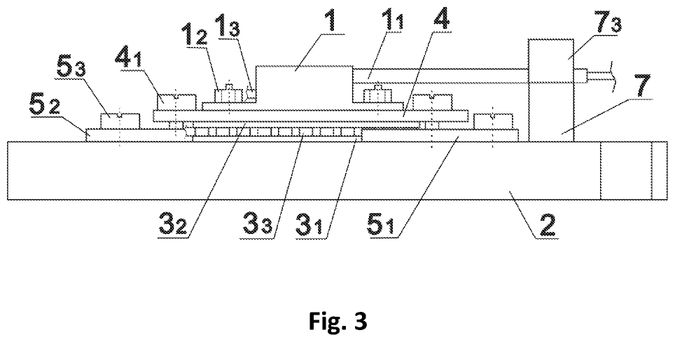

Referring now to FIG. 1, FIG. 2, FIG. 3 in which an assembly of a temperature regulating device for a semiconductor laser 1 is shown. The assembly of the temperature regulating device comprises a base 2 (in the figures, only a part of the base 2 is shown), at which a flat surface of a part of the device element is used as a thermally conductive base surface 5. The thermally conductive base surface 5 contacts to a lower thermally insulated surface 3₁ of a thermoelectric element 3, which consists of two thermally insulated surfaces 3₁ (lower) and 3₂ (upper) between which a semiconducting layer 3₃ consisting of a set of n-type and p-type semiconductors is disposed. Two wires 3₄ are connected to the semiconducting layer 3₃, to feed electric current. Also, two wires 1₃ are connected to the semiconductor laser 1 to feed electric current.

Furthermore, fixing plates 5₁, 5₂ are rigidly fastened to the thermally conductive base surface 5 by means of fasteners 54. The fixing plates 5₁, 5₂ prevent the thermoelectric element 3 from being displaced longitudinally and transversely along the thermally conductive base surface 5 of the base 2.

The fixing plates 5₁, 5₂, adjoin, with their lateral sides, end faces of the lower thermally insulated surface 3₁ which contacts the thermally conductive base surface 5. This makes it possible to insulate thermally the upper thermally insulated surface 3₂ and lower thermally insulated surface 3₁ from each other.

The fixing plate 5₁ comprises side projections 5₄ which adjoin end faces of the lower thermally insulated surface 3₁ which contacts the thermally conductive base surface 5. The side projections 5₄ of fixing plate 5₁ improve the reliability of the attachment of the thermoelectric element 3 to the thermally conductive base surface 5 of the base 2.

The fixing plate 5₂ is disposed between the wires 3₄ of the semiconducting layer 3₃ of the thermoelectric element 3. The fixing plate 5₂ restricts also the movement of the wires 3₄ where they are connected to the semiconducting layer 3₃ of the thermoelectric element 3 this improving the reliability of both connection and operation of the thermoelectric element 3 this also constituting an advantage of the present invention.

The upper thermally insulated surface 3₂ of the thermoelectric element 3 contacts to a thermally conductive plate 4 rigidly fastened by means of fasteners 4₁ to the thermally conductive base surface 5 of the base 2. The thermally conductive plate 4 is thermally insulated from the thermally conductive base surface 5 through fasteners 4₁ to prevent heat transfer from occurring between the thermally conductive base surface 5 the thermally conductive plate 4.

The fasteners 4₁ restrict also both longitudinal and transverse displacements of the thermoelectric element 3 along the thermally conductive base surface 5.

The semiconductor laser 1 is rigidly fastened to the opposite surface of the thermally conductive plate 4 by means of fasteners 1₂. Also, a temperature sensor 6 is rigidly fastened to the surface of the thermally conductive plate 4 by means of a fastener 6₁.

Furthermore, a bearing pad 7 is rigidly fastened to the thermally conductive base surface 5. Disposed at an upper surface 7₁ of the bearing pad 7 are two projections 7₂, between which a fiber optical output 1₁ of the semiconductor laser 1 is disposed the fiber optical output 1₁ of the semiconductor laser 1 resting against the upper surface 7₁ of the bearing pad 7. A limiting clamp 7₃ is secured to the projections 72 of the bearing pad 7 and presses the fiber optical output 1₁ to the upper surface 7₁ of the bearing pad 7 this improving the reliability of connection of the fiber optical output 1₁ to semiconductor laser 1 when exposed to external mechanical impacts and improving, as a whole, the efficiency of operation of the present invention.

The present invention is manufactured and used as follows. The base 2 of the assembly and the flat thermally conducting surface of the device are provided. The flat thermally conducting surface will be used as the thermally conductive base surface 5, at which the thermoelectric element 3 is placed. The thermally conductive plate 4 is installed at the thermoelectric element 3, and the locations for openings for the fasteners 4₁ of the thermoelectric element 4 and for openings for the fastener 5₄ for the fixing plates 5₁, 5₂ are determined.

In order to ensure a better thermal conductivity, a thermal paste-based thermally conductive layer (not shown in the figures) is formed at the thermally conductive base surface 5, at which layer the lower thermally insulated surface 3₁ of the thermoelectric element 3 which surface contacts to the thermally conductive base surface 5 is disposed. The fixing plates 5₁, 5₂ are then installed, which plates prevent the thermoelectric element 3 from being displaced longitudinally and transversely along the thermally conductive base surface 5.

Then a thermal paste-based thermally conductive layer (not shown in the figures) is also formed at the opposite upper thermally insulated surface 3₂ of the thermoelectric element 3 and then the thermally conductive plate 4 is installed at the upper thermally insulated surfaces 3₂, which plate is rigidly fastened, by means of the fasteners 4₁, to the thermally conductive base surface 5 and is thermally insulate therefrom. Then a thermal paste-based thermally conductive layer (not shown in the figures) is also formed at the opposite surface of the thermally conductive plate 4, and then the semiconductor laser 1 is installed at the thermally conductive plate 4 is rigidly fastened by means of the fasteners 4₁ to the thermally conductive plate 4 with the temperature sensor 6 being also fastened thereto by means of the fastener 6₁.

Thermal insulation of the thermally conductive base surface 5 through the fasteners 4₁ may be accomplished either through making the fasteners 4₁ of thermally insulated materials, such as low thermal conductivity plastics, or though using a sleeve made of thermally insulated materials said sleeve being installed onto the fastener 4₁.

In addition, the bearing pad 7 is installed at the thermally conductive base surface 5, opposite to the fiber optical output 1₁, with the semiconductor laser 1 being disposed at the upper surface 7₁ of the bearing pad 7 between two projections 7₂ thereof with the limiting clamp 7₃ being installed at said projections.

The thermoelectric element 3, the semiconductor laser 1 are then connected via the wires 1₃ and the temperature sensor 6 is connected via the wires 3₄ to the respective systems of their power supply and operation control (not shown in the figures).

The assembly in accordance with the present invention operates as follows: electric current is fed to the semiconductor laser 1 and the thermoelectric element 3 via the wires 1₃ and 3₄, respectively. In the course of operation of the semiconductor laser 1, heat is produced (released) whose part is removed as result of the contact of the case of the semiconductor laser 1 to ambient air while the other part of heat is removed from the semiconductor laser 1 to the thermally conductive plate 4. A part of heat is removed from the thermally conductive plate 4 as a result of contact to ambient air while the other part of heat is removed from the thermally conductive plate 4 to the upper thermally insulated surface 3₂ of the thermoelectric element 3. Heat from the lower thermally insulated surface 3₁, of the thermoelectric element 3 is removed to the thermally conductive base surface 5 for which the flat thermally conducting surface of the base 2 is used. A part of heat is removed from the thermally conductive base surface 5 as a result of its contact to ambient air while the other part of heat is removed to the base 2, which is a component of the assembly and performs the function of a radiator. Due to thermal insulation of the thermally conductive plate 4 from the thermally conductive base surface 5through the fasteners 4₁ heat may not be transferred from the thermally conductive base surface 5 to the thermally conductive plate 4. Temperature readings from the temperature sensor 6 come to the control system, which, based on the readings received, determines the electric current value supplied via the wires 3₄ to the semiconducting layer 3₃ of the thermoelectric element 3. As a result of regulating electric current supply to the semiconducting layer 3₃, the difference of temperatures at the lower thermally insulated surface 3₁ and the upper thermally insulated surface 3₂ of the thermoelectric element 3 is regulated.

In order to replace the thermoelectric element 3, the thermally conductive plate 4 is disconnected from the thermally conductive base surface 5 by removing the fasteners 4₁. The thermoelectric element 3 is then disconnected from the power supply and is removed from the thermally conductive base surface 2, and the thermoelectric element 3 is thereby replaced.

In order to replace the semiconductor laser 1, it is turned off and disconnected from the thermally conductive plate 3 by removing the fastener 1₂. In addition, the present invention makes it possible to perform quickly the inspection and functionality test of the assembly parts this also constituting its advantage.

The present invention has a wide margin for temperature regulation, which ensures the maximum efficient operation of the semiconductor laser to ensure the spectral range required.

Furthermore, the advantages of the present invention include the possibility of its use for various configurations and powers of semiconductor lasers.

The present invention is not limited by the above described embodiments.

The above description contains particulars, which are necessary and sufficient for understanding clearly the essence of the present invention. Particulars, which are apparent to those skilled in the art, and those, which do not promote to a better understanding of the essence of the present invention, are omitted herein.

It will be also appreciated that templates of hole spacing at the thermally conductive base surface may be made to speed up installation.

It will be also appreciated that, in order to ensure thermal insulation, the fasteners may comprise additional thermally insulated pads, inserts made of a thermal insulating material.

It will be also appreciated that the fixing plates may be made of a thermal insulating material.

It will be also appreciated that adhesive compositions may be used as the fasteners.

It will be also appreciated that fiberglass, glass laminate, paper-based laminate, acryl, polyvinyl chloride, for example, may be used as thermal insulating materials.

It will be also appreciated that the fixing plates may rigidly fasten at least two thermoelectric elements to the thermally conductive base surface.

It will be also appreciated that the temperature sensor may, before turning on the semiconductor laser, determine the temperature of the thermally conductive plate and, if this temperature is beyond the allowable operation range of the semiconductor laser, electric current is fed to the thermoelectric element. In the event of negative temperatures of the thermally conductive plate, the polarity of electric current supply to the semiconducting layer of the thermoelectric element is also reversed and, as a result thereof, heat is released at the upper thermally insulated surface of the thermoelectric element to heat the thermally conductive plate till the achievement of predetermined temperatures for the efficient activation of the semiconductor laser, upon activation whereof the polarity of electric current supply to the thermoelectric element is reversed. Since the upper thermally insulated surface of the thermoelectric element and the thermally conductive plate are thermally insulated from each other, and from the thermally conductive base surface as well, the assembly in accordance with the present invention functions efficiently.

Technical Result

The technical result of the present invention is the improvement of the efficiency of temperature regulation for a semiconductor laser operating under exposure to external mechanical impacts along with simplifying the design, installation, and replacement of parts.

What is claimed is:

1. An assembly of a temperature regulating device for a semiconductor laser, which comprises a thermally conductive base surface, which a thermally insulated surface of a thermoelectric element adjoins, the thermoelectric element consisting of two thermally insulated surfaces, between which a semiconducting layer consisting of a set of n-type and p-type semiconductors is disposed; a thermally conductive plate, at the opposite side whereof the semiconducting layer is rigidly fastened, adjoining the opposite thermally insulated surface of the thermoelectric element; said assembly comprising further at least one operating temperature sensor of the semiconductor laser, wherein, as the thermally conducting base surface, a flat thermally conducting surface of said device is used, the assembly further comprising two fixing plates, which are rigidly fastened to said thermally conducting base surface and adjoin opposite lateral sides of the lower thermally conducting surface of the thermoelectric element, which surface contacts to the thermally conducting surface base to prevent both longitudinal and transverse displacements of the thermoelectric element along the thermally conductive base surface, and the thermally conductive plate is rigidly fastened to the thermally conductive base surface and is thermally insulated therefrom.

2. The assembly as claimed in claim 1, wherein at least one of the fixing plates comprises two side projections, which adjoin the lateral sides of the lower thermally insulated surface of the thermoelectric element.

3. The assembly as claimed in claim 1, wherein the assembly further comprises a bearing pad rigidly fastened to the thermally conductive base surface;
two projections are disposed at the upper surface of the bearing pad, between which projections a fiber optical output of the semiconductor laser is arranged, said output resting against the upper surface of the bearing pad.

4. The assembly as claimed in claim 3, wherein the assembly comprises a limiting clamp, which is secured at two projections arranged at the upper surface of the bearing pad.

5. The assembly as claimed in claim 1, wherein the thermoelectric element, the thermally conductive plate, and the semiconductor laser are secured with the help of fasteners.
